(19) United States
(12) Patent Application Publication
(10) Pub. No.: US 2025/0246890 A1
(43) Pub. Date: Jul. 31, 2025

(54) ELECTRICAL DEVICE

(71) Applicants: AUTONETWORKS TECHNOLOGIES, LTD., Mie (JP); SUMITOMO WIRING SYSTEMS, LTD., Mie (JP); SUMITOMO ELECTRIC INDUSTRIES, LTD., Osaka (JP)

(72) Inventors: Koushi IGURA, Osaka (JP); Hiroki SHIMODA, Osaka (JP); Taiji YANAGIDA, Osaka (JP)

(73) Assignees: AUTONETWORKS TECHNOLOGIES, LTD., Mie (JP); SUMITOMO WIRING SYSTEMS, LTD., Mie (JP); SUMITOMO ELECTRIC INDUSTRIES, LTD., Osaka (JP)

(21) Appl. No.: 18/845,290

(22) PCT Filed: Mar. 17, 2023
(86) PCT No.: PCT/JP2023/010765

§ 371 Date: Apr. 11, 2025

(30) Foreign Application Priority Data
Mar. 18, 2022 (JP) 2022-043722

(51) Int. Cl. H02G 5/10; H05K 5/02

(52) U.S. Cl. CPC H02G 5/10; H05K 5/0213

(57) ABSTRACT

An electrical device 1 includes a relay 30 that has a relay terminal 32 and generates heat in response to passage of a current, and an intermediate busbar 50 connected to the relay terminal 32. The intermediate busbar 50 includes: a first busbar strip 51 having a first inner abutting portion 52 connected to the relay terminal 32 and a first separated portion 53 continuous with the first inner abutting portion 52; and a second busbar strip 61 having a first outer abutting portion 54 abutting the first inner abutting portion 52 and a second separated portion 63 continuous with the first outer abutting portion 54 and separated from the first separated portion 53.

### TECHNICAL FIELD

The technology disclosed herein relates to an electrical device.

### BACKGROUND ART

A technology is conventionally known for quickly dissipating heat from a heat-generating component that generates heat in response to passage of current therethrough in an electrical device that includes the heat-generating component. For example, a configuration has been proposed in which, in a relay unit that includes a relay and a busbar electrically connecting the relay to a battery, the busbar connected to a relay terminal of the relay is in thermal contact with a metal case via an insulating thermal conductive sheet (see Patent Document 1). Heat generated from the relay during the passage of current is transferred from the relay terminal to the busbar, and from the busbar to the case via the thermal conductive sheet, and is dissipated to the outside. This prevents the temperature of the relay from rising locally.

### CITATION LIST

### Patent Documents

Patent Document 1: JP 2018-93711A

### SUMMARY OF INVENTION

### Technical Problem

In the above configuration, a large current from the battery flows through the heat-generating component, and the amount of heat generated from the heat-generating component is accordingly relatively large. However, there has recently been a demand for downsizing of electrical devices, and there is therefore a need to dispose a component for heat dissipation in a limited space and dissipate heat efficiently.

### Solution to Problem

An electrical device disclosed herein includes: a heat-generating component that has a terminal and generates heat in response to passage of a current; and a busbar connected to the terminal, wherein the busbar includes: one busbar strip having: an inner abutting portion connected to the terminal; and one separated portion continuous with the inner abutting portion; and another busbar strip having: an outer abutting portion abutting the inner abutting portion; and another separated portion continuous with the outer abutting portion and separated from the one separated portion.

### Advantageous Effects of Invention

According to the electrical device disclosed herein, both downsizing and improved heat dissipation efficiency can be achieved.

### BRIEF DESCRIPTION OF DRAWINGS

FIG. 1 is a perspective view of an electrical device of Embodiment 1.

FIG. 2 is an exploded perspective view of the electrical device of Embodiment 1.

FIG. 3 is a perspective view of a base member of Embodiment 1.

FIG. 4 is a perspective view of a cover of Embodiment 1.

FIG. 5 is an exploded perspective view of the base member, a relay, a fuse, and busbars of Embodiment 1.

FIG. 6 is a perspective view of an intermediate busbar of Embodiment 1.

FIG. 7 is a perspective view of a relay-side busbar of Embodiment 1.

FIG. 8 is a plan view of the base member, the relay, the fuse, and the busbars of Embodiment 1.

FIG. 9 is an exploded perspective view of an electrical device of Embodiment 2.

FIG. 10 is a perspective view of an intermediate busbar of Embodiment 2.

FIG. 11 is an exploded perspective view of an electrical device of Embodiment 3.

FIG. 12 is an exploded perspective view of a base member, a relay, a fuse, and busbars of Embodiment 3.

FIG. 13 is a perspective view of an intermediate busbar of Embodiment 3.

FIG. 14 is a perspective view of an electrical device of Embodiment 4.

FIG. 15 is an exploded perspective view of the electrical device of Embodiment 4 from which a cover is removed.

FIG. 16 is a plan view of a base member, a relay, a fuse, and busbars according to Embodiment 4.

FIG. 17 is a perspective view of the base member of Embodiment 4.

FIG. 18 is a bottom view of the cover of Embodiment 4.

FIG. 19 is a cross-sectional view taken at a fastening position of the relay and the busbars of Embodiment 4.

FIG. 20 is a cross-sectional view taken at a fastening position of the fuse and a busbar of Embodiment 4.

FIG. 21 is an exploded perspective view of the base member, the relay, the fuse, and the busbars of Embodiment 4.

FIG. 22 is a perspective view of an intermediate busbar of Embodiment 4.

### DESCRIPTION OF EMBODIMENTS

### Summary of Embodiments

(1) An electrical device disclosed herein includes: a heat-generating component that has a terminal and generates heat in response to passage of a current; and a busbar connected to the terminal, wherein the busbar includes: one busbar strip having: an inner abutting portion connected to the terminal; and one separated portion continuous with the inner abutting portion; and another busbar strip having: an outer abutting portion abutting the inner abutting portion; and another separated portion continuous with the outer abutting portion and separated from the one separated portion.

With the above configuration, the surface area of the busbar can be increased to improve heat dissipation efficiency, while the busbar can be disposed within a limited space, thereby achieving both downsizing of the electrical device and improved the heat dissipation efficiency.

(2) In the electrical device according to the above item (1), an area of an inner surface, which faces the other separated portion, of the one separated portion may account for 30% or more of an area of an entire inner surface, which faces the other busbar strip, of the one busbar strip. With this configuration, heat dissipation efficiency can be improved reliably.

(3) In the electrical device according to the above item (1) or (2), the one separated portion and the other separated portion may be disposed in a space adjacent to the heat-generating component. With this configuration, heat generation efficiency can be improved while avoiding an increase in the size of the electrical device by effectively using the space adjacent to the heat-generating component.

(4) In the electrical device according to any of the above items (1) to (3), the busbar may have a rising wall rising from the outer abutting portion or the inner abutting portion. With this configuration, the volume of the busbar can be increased near the connecting section to the terminal that is likely to generate heat. Particularly, a temperature rise can be prevented during a short-term current passage when a large current flows for a short time period. Further, the increase in the surface area of the busbar improves the heat dissipation efficiency.

(5) In the electrical device according to any of the above items (1) to (4), the electrical device may include a plurality of the heat-generating components, the one busbar strip may have one inner abutting portion serving as the inner abutting portion and one outer abutting portion serving as the outer abutting portion that are continuous with the one separated portion, and the other busbar strip may have another inner abutting portion serving as the inner abutting portion and another outer abutting portion serving as the outer abutting portion that are continuous with the other separated portion, and the one inner abutting portion and the other outer abutting portion may be placed in this order over the terminal of one heat-generating component, of the plurality of heat-generating components, and the other inner abutting portion and the one outer abutting portion may be placed in this order over the terminal of another heat-generating component, of the plurality of heat-generating components.

The order of placing the one busbar strip and the other busbar strip over the terminal of each of the two respective heat-generating components is thus reversed on the one heat-generating component side and the other heat-generating component side. This can make the path resistance values of the two busbar strips equal.

(6) In the electrical device of any of the above items (1) to (5), the busbar may have a ventilation tube portion having a tubular shape and constituted by the one separated portion and the other separated portion. With this configuration, a space for the air to pass through can be secured between the one separated portion and the other separated portion, and the heat dissipation efficiency can be improved.

(7) In the electrical device of any of the above items (1) to (5), the one separated portion and the other separated portion may be perpendicular to each other. With this configuration, the separated portions can be disposed even when the space adjacent to the heat-generating component is small, and the electrical device can be downsized.

(8) In the electrical device of the above item (7), at least either the one separated portion or the other separated portion may extend along an outer face of the heat-generating component. With this configuration, heat from the heat-generating component is efficiently transferred, and the heat dissipation efficiency can be improved.

(9) The electrical device of any of the above items (1) to (8) may further include a case housing the heat-generating component and the busbar, and the case may include a case wall having a ventilation hole. With this configuration, air can flow within the case, and the heat dissipation efficiency can be improved.

(10) In the electrical device of the above item (9), the case may include the case wall extending along the one separated portion or the other separated portion. With this configuration, the separated portions receive air flowing from the ventilation hole, thereby improving the heat generation efficiency.

(11) The electrical device of the above item (10) may further include a case housing the heat-generating component and the busbar, and the case may include a case wall that has a ventilation hole and is perpendicular to the ventilation tube portion. With this configuration, air flowing from the ventilation hole can smoothly pass within the ventilation tube portion, and the efficiency of heat dissipation from the ventilation tube portion improves.

(12) In the electrical device of any of the above items (1) to (3), the other separated portion may extend linearly from the outer abutting portion, the one separated portion may have: one intersecting portion extending in a first direction intersecting the other separated portion; and one inclined portion connecting the inner abutting portion to the one intersecting portion, and the one inclined portion may incline so as to extend away from the other separated portion while approaching the one intersecting portion. It is preferable that the first direction is a direction forming an angle substantially from 60° to 120° with the other separated portion, and may be, for example, a perpendicular direction forming 90° with the other separated portion.

With this configuration, providing the one inclined portion results in a decrease in the surface area of the one intersecting portion, but the amount of increase in the surface area of the one inclined portion is greater than the amount of decrease in the surface area of the one intersecting portion, so that the surface area of the busbar increases. Further, providing the one inclined portion increases the surface area of the other separated portion, thus increasing the surface area of the busbar. Thus, the surface area of the busbar can be increased in the vicinity of the connecting section to the terminal that is likely to generate heat. Particularly, a temperature rise can be prevented during short-term current passage when a large high current flows for a short time period.

(13) The electrical device of the above items (1) to (3) and (12) may further include a case housing the heat-generating component and the busbar, and the case may include: an inner case wall extending along an inner face of the busbar; and an outer case wall extending along an outer face of the busbar, the inner case wall and the outer case wall being integrated. With this configuration, heat is more easily transferred from the inner face of the busbar to the inner case wall, and from the outer face of the busbar to the outer case wall, thus improving the heat dissipation efficiency of the busbar compared to the case of dissipating heat into the air.

(14) In the electrical device of the above items (1) to (3), (12), and (13), the busbar may further have at least either: one extension portion extending from the one separated portion toward a first side region located on a side of the heat-generating component; or another extension portion extending from the other separated portion toward a second side region located on an opposite side to the first side region relative to the heat-generating component.

With this configuration, at least either one of the extension portions increases the surface area of the busbar, thereby improving the heat dissipation efficiency of the busbar. Further, the first side region and the second side region of the heat-generating component are low-temperature regions separated from the terminals, which are likely to be heat sources. Thus, the heat dissipation efficiency in at least either one of the extension portions can be improved.

### DETAILS OF EMBODIMENTS

Specific examples of the technology disclosed herein will be described below with reference to the drawings. Note that the present invention is not limited to these examples but is defined by the claims, and is intended to include all modifications made within the meaning and scope equivalent to the claims.

### Embodiment 1

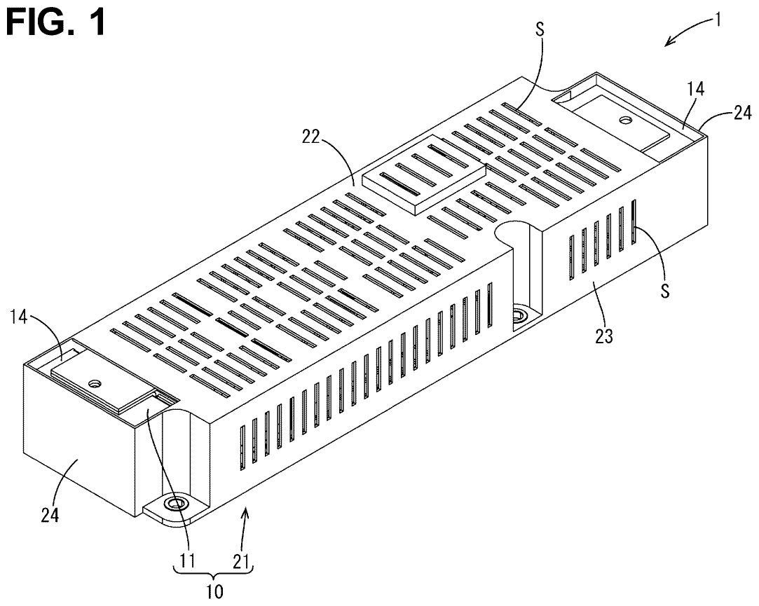

Embodiment 1 will be described with reference to FIGS. 1 to 8. An electrical device 1 of the present embodiment is installed in a vehicle such as an electric vehicle or a hybrid vehicle, and is disposed in a power supply path from a power source, such as a battery, to a load, such as a motor.

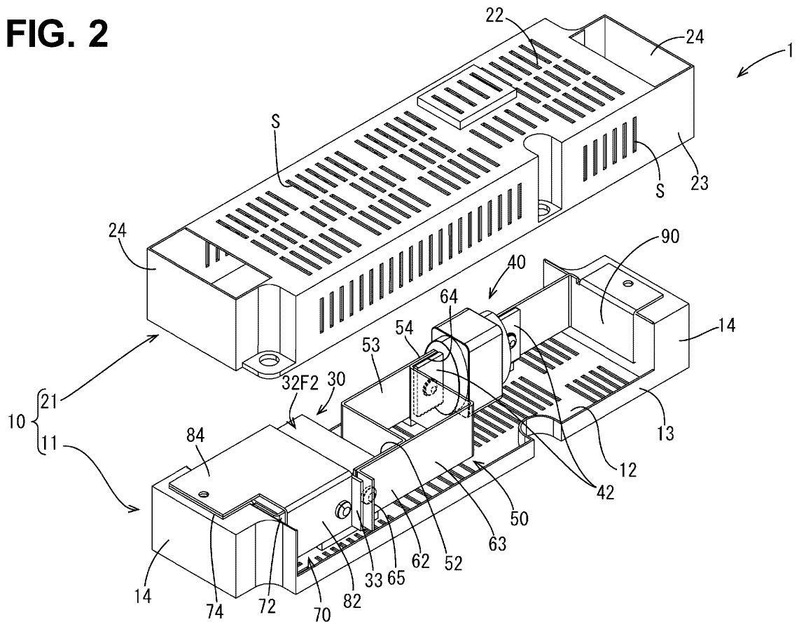

As shown in FIGS. 1 and 2, the electrical device 1 includes a relay 30 (an example of a heat-generating component), a fuse 40 (an example of a heat-generating component), an intermediate busbar 50 (an example of a busbar), a relay-side busbar 70 (an example of a busbar), a fuse-side busbar 90, and a case 10 that houses these components.

### Case 10

The case 10 is made of synthetic resin, and has a base member 11 to which the relay 30 and the fuse 40 are fixed, and a cover 21 that is fitted to the base member 11 and covers the relay 30, the fuse 40, and the busbars 50, 70, and 90, as shown in FIG. 2.

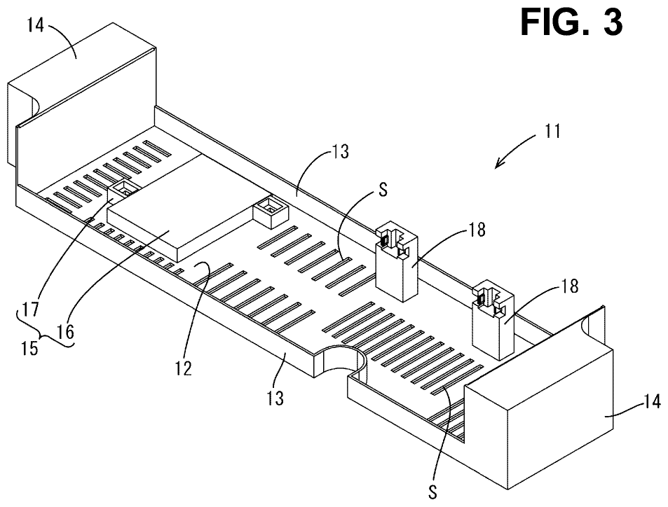

As shown in FIG. 3, the base member 11 includes a base plate 12 (an example of a case wall) having a rectangular plate-shape, two partition walls 13 rising from two respective long sides of the base plate 12, and two connection stages 14 rising from two respective short sides of the base plate 12. A relay mount 15 for attaching the relay 30 and two attachment poles 18 for attaching the fuse 40 are disposed in one face of the base plate 12. The relay mount 15 has a mount body 16 for supporting the relay 30 and two attachment protrusions 17 protruding from the mount body 16. The two attachment poles 18 each has a rectangular prismatic shape. A nut (not shown) is provided in each of the attachment protrusions 17 and the attachment poles 18 by means of a known method, such as insert molding or press fitting.

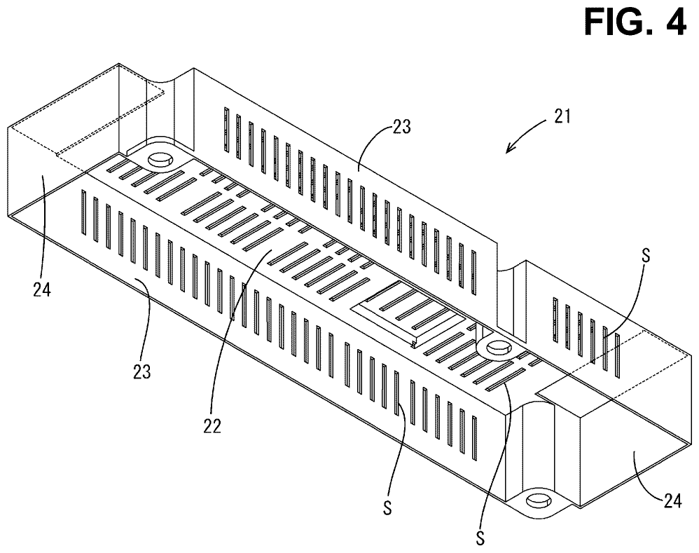

As shown in FIGS. 2 and 4, the cover 21 has a rectangular plate shape, and has a top wall 22 (an example of a case wall) facing the base plate 12, two first side walls 23 (each being an example of a case wall) extending from two respective long sides of the top wall 22 along the two respective partition walls 13, and two second side walls 24 extending from two respective short sides of the top wall 22.

The base plate 12, the top wall 22, and the two first side walls 23 have a plurality of slits S (each being an example of a ventilation hole) for allowing the air to flow inside the case 10, as shown in FIGS. 3 and 4. It is preferable that each slit S is as large as possible to the extent that an operator's finger cannot be inserted therein.

Relay 30 and fuse 40

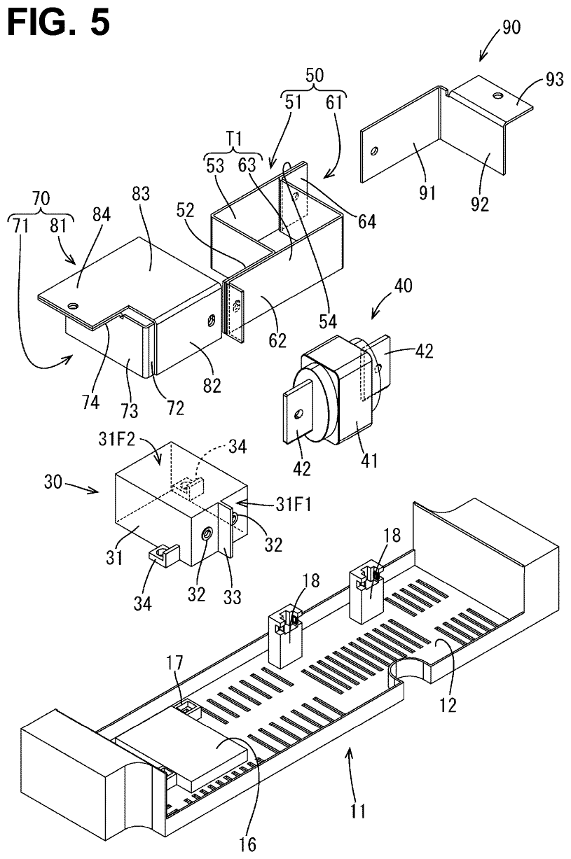

The relay 30 is a mechanical relay through which a relatively large current from the vehicle battery is passed, and has a relay body 31, two relay terminals 32 (each being an example of a terminal) provided in one face (terminal face 31F1) out of a plurality of outer faces of the relay body 31, a wall 33, and two attachment pieces 34 protruding from the relay body 31, as shown in FIG. 5. The two relay terminals 32 are each formed as a nut to which a bolt serving as a fastening member is fastened. The wall 33 is located between the two relay terminals 32 and sets a creepage distance between the two relay terminals 32.

The fuse 40 has a fuse body 41 and two fuse terminals 42 (each being an example of a terminal) protruding from the fuse body 41, as shown in FIG. 5. The fuse terminals 42 are made of metal and has a plate shape.

### Busbars 50, 70, and 90

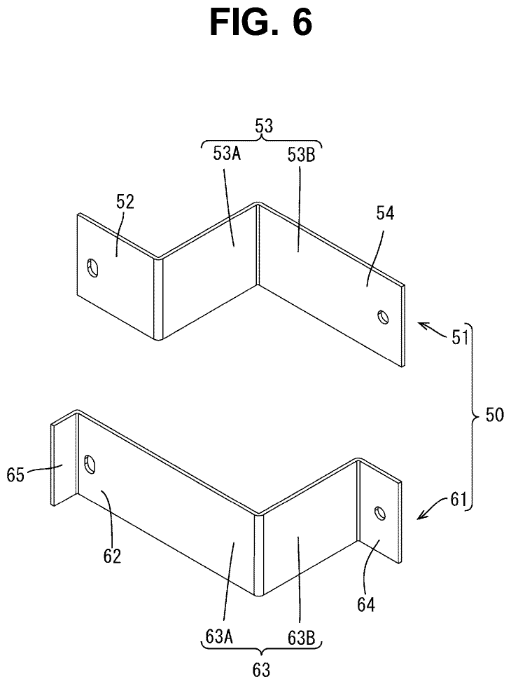

The intermediate busbar 50 is a busbar that connects the relay 30 to the fuse 40, and includes a first busbar strip 51 (an example of one busbar strip) and a second busbar strip 61 (an example of another busbar strip), as shown in FIGS. 5 and 6.

The first busbar strip 51 is a member obtained by punching and bending a metal plate material, and has a first inner abutting portion 52 (an example of an inner abutting portion and one inner abutting portion), which is connected to one relay terminal 32, a first separated portion 53 (an example of one separated portion), which is continuous with the first inner abutting portion 52, and a first outer abutting portion 54 (an example of an outer abutting portion and one outer abutting portion), which is continuous with the first separated portion 53 and connected to one fuse terminal 42, as shown in FIG. 6. The first inner abutting portion 52 has a flat plate shape. The first separated portion 53 has an L-shape, and has a first vertical plate portion 53A, which has a flat plate shape and extends perpendicularly from the first inner abutting portion 52, and a first lateral plate portion 53B, which has a flat plate shape and extends perpendicularly from the first vertical plate portion 53A. The first outer abutting portion 54 has a flat plate shape and extends from the first lateral plate portion 53B in the same plane.

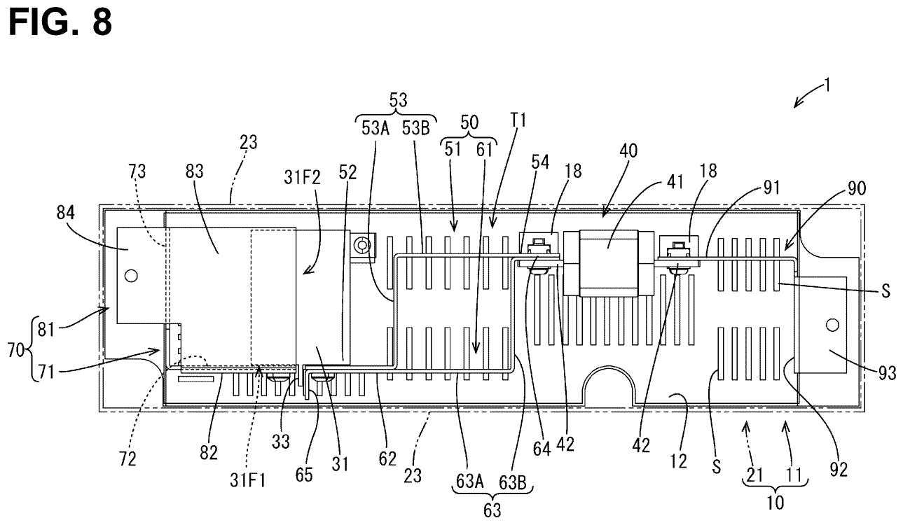

The second busbar strip 61 is a member obtained by punching and bending a metal plate material, and has a second outer abutting portion 62 (an example of an outer abutting portion and another outer abutting portion), which is connected to one relay terminal 32, a second separated portion 63 (an example of another separated portion), which is continuous with the second outer abutting portion 62, a second inner abutting portion 64 (an example of an inner abutting portion and another inner abutting portion), which is continuous with the second separated portion 63 and connected to one fuse terminal 42, and a rising wall 65 extending from the second outer abutting portion 62, as shown in FIGS. 6 and 8. The second outer abutting portion 62 has a flat plate shape. The second separated portion 63 has an L-shape, and has a second lateral plate portion 63A, which has a flat plate shape and extends from the second outer abutting portion 62 in the same plane, and a second vertical plate portion 63B, which has a flat plate shape and extends perpendicularly from the second lateral plate portion 63A The second inner abutting portion 64 has a flat plate shape and extends perpendicularly from the second vertical plate portion 63B. The rising wall 65 is adjacent to the second outer abutting portion 62 and extends perpendicularly from an edge of the second outer abutting portion 62 on the opposite side to the second separated portion 63.

As shown in FIGS. 5 and 8, the first inner abutting portion 52 and the second outer abutting portion 62 are placed over each other, the first outer abutting portion 54 and the second inner abutting portion 64 are placed over each other, and the first separated portion 53 and the second separated portion 63 are separated from each other. It is preferable that the first separated portion 53 and the second separated portion 63 are separated by a distance that does not allow them to transfer heat to each other. The first vertical plate portion 53A and the second vertical plate portion 63B are parallel with each other, the first lateral plate portion 53B and the second lateral plate portion 63A are parallel with each other, and the first separated portion 53 and the second separated portion 63 constitute a ventilation tube portion T1 having a tubular shape. The area of the inner surface, which faces the second separated portion 63, of the first separated portion 53 accounts for 30% or more of the area of the entire inner surface, which faces the second busbar strip 61, of the first busbar strip 51. Similarly, the area of the inner surface, which faces the first separated portion 53, of the second separated portion 63 accounts for 30% or more of the area of the entire inner surface, which faces the first busbar strip 51, of the second busbar strip 61.

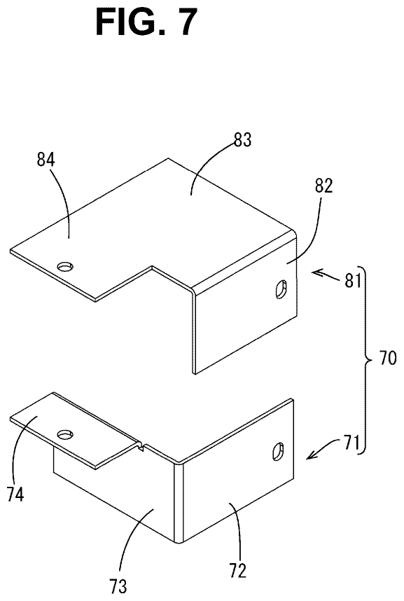

The relay-side busbar 70 is a busbar for external connection that is connected to the relay 30, and includes a third busbar strip 71 (an example of one busbar strip) and a fourth busbar strip 81 (an example of another busbar strip), as shown in FIGS. 5 and 7.

The third busbar strip 71 is a member obtained by punching and bending a metal plate material, and has a third inner abutting portion 72 (an example of an inner abutting portion), which is connected to one relay terminal 32, a third separated portion 73 (an example of one separated portion), which is continuous with the third inner abutting portion 72, and a first external connection portion 74 for external connection, which is continuous with the third separated portion 73, as shown in FIG. 7. The third inner abutting portion 72 has a flat plate shape. The third separated portion 73 has a flat plate shape and extends perpendicularly from the third inner abutting portion 72. The first external connection portion 74 has a flat plate shape and extends perpendicularly from the third separated portion 73.

The fourth busbar strip 81 is a member obtained by punching and bending a metal plate material, and has a fourth outer abutting portion 82 (an example of an outer abutting portion), which is connected to one relay terminal 32, a fourth separated portion 83 (an example of another separated portion), which is continuous with the fourth outer abutting portion 82, and a second external connection portion 84 for external connection, which is continuous with the fourth separated portion 83. The fourth outer abutting portion 82 has a flat plate shape. The fourth separated portion 83 has a flat plate shape and extends perpendicularly from the fourth outer abutting portion 82. The second external connection portion 84 has a flat plate shape and extends from the fourth separated portion 83 in the same plane.

As shown in FIGS. 5 and 8, the third inner abutting portion 72 and the fourth outer abutting portion 82 are placed over each other, the first external connection portion 74 and the second external connection portion 84 are placed over each other, and the third separated portion 73 and the fourth separated portion 83 are separated from each other. The third separated portion 73 and the fourth separated portion 83 are perpendicular to each other. It is preferable that the third separated portion 73 and the fourth separated portion 83 are separated by a distance that does not allow them to transfer heat to each other. The area of the inner surface, which faces the fourth separated portion 83, of the third separated portion 73 accounts for 30% or more of the area of the entire inner surface, which faces the fourth busbar strip 81, of the third busbar strip 71. Similarly, the area of the inner surface, which faces the third separated portion 73, of the fourth separated portion 83 accounts for 30% or more of the area of the entire inner surface, which faces the third busbar strip 71, of the fourth busbar strip 81.

The fuse-side busbar 90 is a busbar for external connection that is connected to the fuse 40. The fuse-side busbar 90 is a member obtained by punching and bending a metal plate material, and has a first fuse connecting portion 91, which has a flat plate shape and is connected to one fuse terminal 42, a third external connection portion 93 for external connection that has a flat plate shape, and a first joint portion 92, which has a flat plate shape and connects the first fuse connecting portion 91 to the third external connection portion 93, as shown in FIG. 5.

### Assembly Process of Electrical Device 1

One example of an assembly process of the electrical device 1 having the above configuration will be described below.

First, the relay body 31 is placed on the relay mount 15 in a direction in which the terminal face 31F1 is perpendicular to the base plate 12. The two attachment pieces 34 are screwed to the two respective attachment protrusions 17, thereby fixing the relay 30 to the base member 11.

Next, the intermediate busbar 50 is disposed such that the first inner abutting portion 52 is placed over one relay terminal 32 provided in the terminal face 31F1, and such that the second outer abutting portion 62 is placed over the first inner abutting portion 52. The first inner abutting portion 52 and the second outer abutting portion 62 are screwed and fixed to the relay terminal 32. In this state, the rising wall 65 is adjacent to the wall 33.

The relay-side busbar 70 is disposed such that the third inner abutting portion 72 is placed over the other relay terminal 32 provided in the terminal face 31F1, and such that the fourth outer abutting portion 82 is placed over the third inner abutting portion 72. The third inner abutting portion 72 and the fourth outer abutting portion 82 are screwed and fixed to the relay terminal 32.

When the intermediate busbar 50 has been fixed to the relay 30, the first outer abutting portion 54 has been placed over a side face of one attachment pole 18, and the second inner abutting portion 64 has been placed over the first outer abutting portion 54. In this state, one fuse terminal 42 is placed over the second inner abutting portion 64, and the first outer abutting portion 54, the second inner abutting portion 64, and the fuse terminal 42 are screwed and fixed to the attachment pole 18.

Further, the first fuse connecting portion 91 is placed over the other attachment pole 18, the other fuse terminal 42 is placed over the first fuse connecting portion 91, and the first fuse connecting portion 91 and the fuse terminal 42 are screwed and fixed to the attachment pole 18.

Fixation of the relay 30, the fuse 40, and the busbars 50, 70, and 90 to the base member 11 is thus completed. Lastly, the cover 21 is fitted to the base member 11, thereby completing assembly of the electrical device 1. When the assembly of the electrical device 1 is complete, the relay 30 is disposed in an orientation in which the terminal face 31F1 is perpendicular to the base plate 12, and the fuse 40 is disposed in an orientation in which the two fuse terminals 42 are perpendicular to the base plate 12.

### Passage of Current Through Electrical Device 1

The relay 30 and the fuse 40 generate heat when a current is passed through the electrical device 1 having the above configuration. The heat from the relay 30 and the fuse 40 is dissipated to the outside via the busbars 50, 70, and 90.

Here, the intermediate busbar 50 includes two busbar strips 51 and 61, and has the first separated portion 53 and the second separated portion 63, as shown in FIG. 8. According to the above configuration, the surface area of the intermediate busbar 50 can be increased to improve heat dissipation efficiency, while the intermediate busbar 50 can be disposed within a limited space.

The ventilation tube portion T1 constituted by the first separated portion 53 and the second separated portion 63 is perpendicular to the base plate 12 in a relatively large space between the relay 30 and the fuse 40. Thus disposing the first separated portion 53 and the second separated portion 63 using the space between the relay 30 and the fuse 40 can improve the heat generation efficiency while avoiding an increase in the size of the electrical device 1. Further, the ventilation tube portion T1 having a tubular shape being constituted by the first separated portion 53 and the second separated portion 63 can secure a space for the air to pass through between the first separated portion 53 and the second separated portion 63 and improve the heat dissipation efficiency. Furthermore, disposing the first separated portion 53 and the second separated portion 63 perpendicularly to the base plate 12 can efficiently cause convection of air and improve the heat generation efficiency.

The first inner abutting portion 52 and the second outer abutting portion 62 are placed in this order over the relay terminal 32 in a connection region of the intermediate busbar 50 and the relay terminal 32, and the second inner abutting portion 64 and the first outer abutting portion 54 are placed in this order over the fuse terminal 42 in a connecting region of the intermediate busbar 50 and the fuse terminal 42. That is, the order of placing the first busbar strip 51 and the second busbar strip 61 over the relay terminal 32 and the fuse terminal 42 is reversed on the relay 30 side and the fuse 40 side. Here, on the relay 30 side, contact resistance occurs at an interface between the first inner abutting portion 52 and the second outer abutting portion 62, and the resistance of the second outer abutting portion 62 located on the outer side is larger. Meanwhile, on the fuse 40 side, contact resistance occurs at an interface between the second inner abutting portion 64 and the first outer abutting portion 54, and the resistance of the first outer abutting portion 54 located on the outer side is larger. The path resistance values (resistance value per busbar strip) of the two busbar strips 51 and 61 can be made equal by reversing the order of placing the first busbar strip 51 and the second busbar strip 61 over the relay terminal 32 and the fuse terminal 42 on the relay 30 side and the fuse 40 side.

The second busbar strip 61 has the rising wall 65. Here, the relay 30 of the present embodiment is a mechanical relay, and has a fixed contact, a movable piece that can be brought into contact with and separated from the fixed contact, and an excitation coil that switches the connection state between the movable piece and the fixed contact. The relay 30 of this type is likely to generate heat from a region around the internal fixed contact, which is connected to the relay terminal 32. The second busbar strip 61 having the rising wall 65 adjacent to the second outer abutting portion 62 connected to the relay terminal 32 can increase the surface area of the intermediate busbar 50 in the vicinity of the connecting section to the relay terminal 32 that is likely to generate heat. Particularly, a temperature rise can be prevented during short-term current passage when a large current flows for a short time period. Further the surface area of the intermediate busbar 50 increases, which allows the heat from the relay 30 to be dissipated efficiently.

Here, the relay-side busbar 70 also includes two busbar strips 71 and 81, and has the third separated portion 73 and the fourth separated portion 83 that are separated from each other. With this configuration, the surface area of the relay-side busbar 70 can be increased to improve the heat dissipation efficiency, while the relay-side busbar 70 can be disposed within a limited space.

Further, the third separated portion 73 and the fourth separated portion 83 are perpendicular to each other in a space between the relay 30 and the case 10. With this configuration, the third separated portion 73 and the fourth separated portion 83 can be disposed even when the space adjacent to the relay 30 is relatively small. Further, the fourth separated portion 83 extends along an outer face 31F2 of the relay 30 that is different from the terminal face 31F1. This allows the heat from the relay 30 to be easily transferred to the relay-side busbar 70, thus enabling efficient heat dissipation.

The base plate 12, the top wall 22, and the two first side walls 23 each have a plurality of slits S. This allows air to flow inside the case 10 and improves the efficiency of heat dissipation from the busbars 50, 70, and 90. In particular, the first lateral plate portion 53B and the second lateral plate portion 63A extend along the two respective first side walls 23, thus making the first lateral plate portion 53B and the second lateral plate portion 63A receive the air flowing in from the slits S in the first side walls 23 and improving the efficiency of heat dissipation from the intermediate busbar 50. Further, the third separated portion 73 extends along the top wall 22, thus making the third separated portion 73 receive the air flowing in from the slits S in the top wall 22 and improving the efficiency of heat dissipation from the relay-side busbar 70. Furthermore, the base plate 12 and the top wall 22, which are perpendicular to the ventilation tube portion T1, have the slits S. This allows the air flowing in from the slits S to smoothly pass inside the ventilation tube portion T1 and improves the efficiency of heat dissipation from the ventilation tube portion T1.

### Operation and Effect

As described above, according to the present embodiment, the electrical device 1 includes the relay 30 that has the relay terminals 32 and generates heat in response to passage of a current, and the intermediate busbar 50 and the relay-side busbar 70 that are connected to the respective relay terminals 32. The intermediate busbar 50 includes: the first busbar strip 51 that has the first inner abutting portion 52 connected to one relay terminal 32, and the first separated portion 53 continuous with the first inner abutting portion 52; and the second busbar strip 61 that has the first outer abutting portion 54 abutting the first inner abutting portion 52, and the second separated portion 63 continuous with the first outer abutting portion 54 and separated from the first separated portion 53. The relay-side busbar 70 includes: the third busbar strip 71 that has the third inner abutting portion 72 connected to the relay terminal 32, and the third separated portion 73 continuous with the third inner abutting portion 72; and the fourth busbar strip 81 that has the fourth outer abutting portion 82 abutting the third inner abutting portion 72, and the fourth separated portion 83 continuous with the fourth outer abutting portion 82 and separated from the third separated portion 73.

According to the above configuration, the surface areas of the busbars 50 and 70 can be increased to improve the heat dissipation efficiency, while the busbars 50 and 70 can be disposed within a limited space, thereby achieving both downsizing of the electrical device 1 and improved heat dissipation efficiency.

The area of the inner surface, which faces the second separated portion 63, of the first separated portion 53 of the intermediate busbar 50 accounts for 30% or more of the area of the entire inner surface, which faces the second busbar strip 61, of the first busbar strip 51. Similarly, the area of the inner surface, which faces the first separated portion 53, of the second separated portion 63 accounts for 30% or more of the area of the entire inner surface, which faces the first busbar strip 51, of the second busbar strip 61. Further, the area of the inner surface, faces the fourth separated portion 83, of the third separated portion 73 accounts for 30% or more of the area of the entire inner surface, faces the fourth busbar strip 81, of the third busbar strip 71. Similarly, the area of the inner surface, which faces the third separated portion 73, of the fourth separated portion 83 accounts for 30% or more of the area of the entire inner surface, which faces the third busbar strip 71, of the fourth busbar strip 81. With this configuration, the heat dissipation efficiency can be improved reliably.

The first separated portion 53 and the second separated portion 63 are disposed in a space adjacent to the relay 30 and the fuse 40. The third separated portion 73 and the fourth separated portion 83 are disposed in a space adjacent to the relay 30. With this configuration, the heat generation efficiency can be improved while avoiding an increase in the size of the electrical device 1 by effectively using the space adjacent to the relay 30 and the fuse 40.

The intermediate busbar 50 has the rising wall 65 rising from the second outer abutting portion 62. With this configuration, the volume of the intermediate busbar 50 can be increased in the vicinity of the connecting sections to the relay terminals 32 that is likely to generate heat. Particularly, a temperature rise can be prevented during short-term current passage when a large current flows for a short time period. Further, the increase in the surface area of the intermediate busbar 50 improves the heat dissipation efficiency.

The electrical device 1 includes the relay 30 and the fuse 40. The first busbar strip 51 has the first inner abutting portion 52 and the first outer abutting portion 54 that are continuous with the first separated portion 53. The second busbar strip 61 has the second inner abutting portion 64 and the second outer abutting portion 62 that are continuous with the second separated portion 63. The first inner abutting portion 52 and the second outer abutting portion 62 are placed in this order over one relay terminal 32 of the relay 30. The second inner abutting portion 64 and the first outer abutting portion 54 are placed in this order over one fuse terminal 42 of the fuse 40.

Thus, the order of placing the first busbar strip 51 and the second busbar strip 61 over the relay terminal 32 of the relay 30 and the fuse terminal 42 of the fuse 40 is reversed on the relay 30 side and the fuse 40 side. This can make path resistance values of the two busbar strips 51 and 61 equal.

The third separated portion 73 and the fourth separated portion 83 are perpendicular to each other. With this configuration, the separated portions 73 and 83 can be disposed even when the space adjacent to the relay 30 is small, and the electrical device 1 can be downsized.

The fourth separated portion 83 extends along the outer face 31F2 of the relay 30. With this configuration, heat from the relay 30 can be efficiently transferred to the relay-side busbar 70, and the heat dissipation efficiency can be improved.

The electrical device 1 includes the case 10 housing the relay 30, the fuse 40, and the busbars 50 and 70. The case 10 includes the base plate 12, the top wall 22, and the two first side walls 23 that have the slits S. With this configuration, air can flow inside the case 10, and the heat dissipation efficiency can be improved.

The two first side walls 23 extend along the first lateral plate portion 53B of the first separated portion 53 and the second lateral plate portion 63A of the second separated portion 63, respectively. The top wall 22 extends along the fourth separated portion 83. With this configuration, the first lateral plate portion 53B, the second lateral plate portion 63A, and the fourth separated portion 83 receive the air flowing in from the slits S, thereby improving the heat generation efficiency.

The intermediate busbar 50 has the ventilation tube portion T1 that has a tubular shape and is constituted by the first separated portion 53 and the second separated portion 63. With this configuration, a space for the air to pass through can be secured between the first separated portion 53 and the second separated portion 63, and the heat dissipation efficiency can be improved.

The base plate 12 and the top wall 22 are perpendicular to the ventilation tube portion T1. With this configuration, the air flowing in from the slits S can smoothly pass inside the ventilation tube portion T1, thus improving the efficiency of heat dissipation from the ventilation tube portion T1.

### Embodiment 2

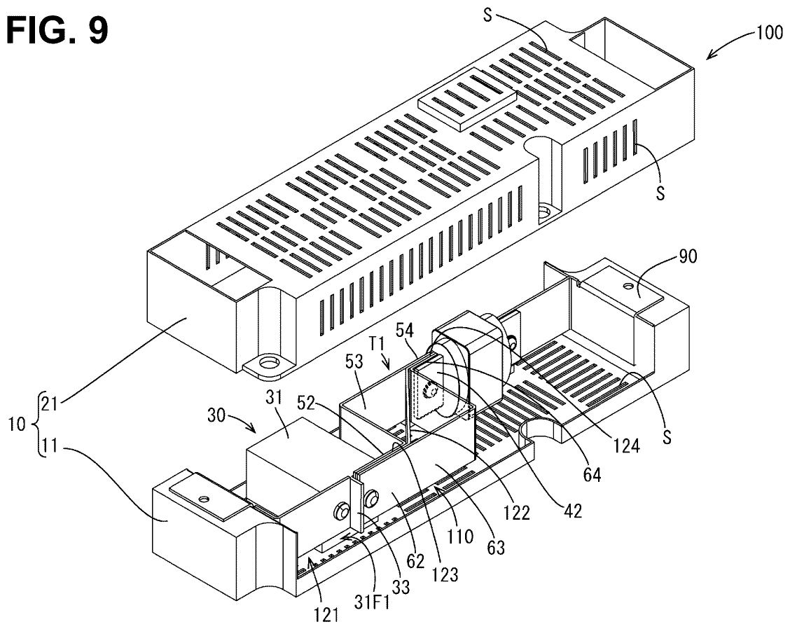

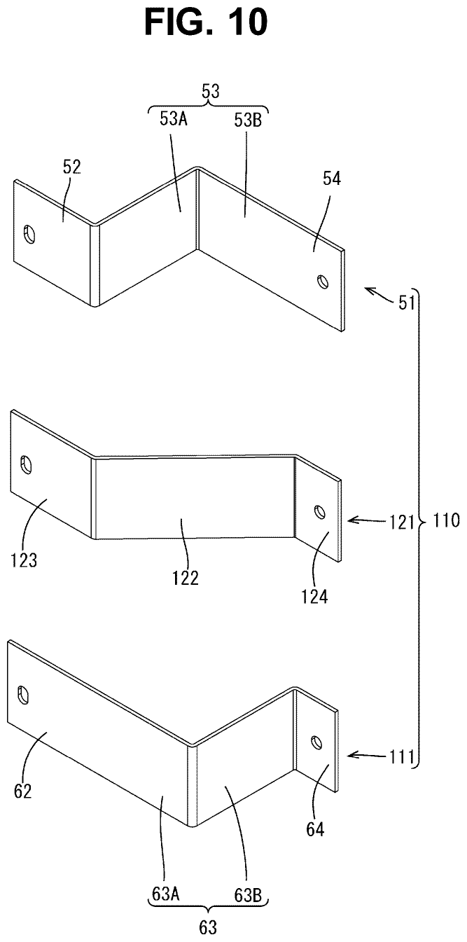

Embodiment 2 will be described with reference to FIGS. 9 and 10. An electrical device 100 of Embodiment 2 has a different configuration of an intermediate busbar 110 from Embodiment 1. Note that the same configurations as Embodiment 1 are assigned the same reference numerals, and description thereof is omitted.

An intermediate busbar 110 includes a first busbar strip 51 (an example of one busbar strip), a fifth busbar strip 111 (an example of another busbar strip), and a sixth busbar strip 121, as shown in FIG. 10. The first busbar strip 51 has the same configuration as Embodiment 1. The fifth busbar strip 111 has the same configuration as the second busbar strip 61 of Embodiment 1 except that the rising wall 65 is not provided.

The sixth busbar strip 121 (an example of another busbar strip) has a fifth separated portion 122 (an example of another separated portion) having a flat plate shape, and two intermediate abutting portions 123 and 124 (each being an example of an outer abutting portion) extending diagonally from two respective ends of the fifth separated portion 122.

In a connection region of the intermediate busbar 110 and one relay terminal 32, the first inner abutting portion 52, one intermediate abutting portion 123, and the second outer abutting portion 62 are placed in this order over the relay terminal 32 provided in the terminal face 31F1, as shown in FIG. 9. In a connecting region of the intermediate busbar 110 and one fuse terminal 42, the second inner abutting portion 64, the other intermediate abutting portion 124, and the first outer abutting portion 54 are placed in this order over the fuse terminal 42. The first separated portion 53, the second separated portion 63, and the fifth separated portion 122 are separated from each other. A ventilation tube portion T1 having a tubular shape is constituted by the first separated portion 53 and the second separated portion 63, and the fifth separated portion 122 is disposed diagonally between the first separated portion 53 and the second separated portion 63.

This configuration also achieves the same operation and effect as Embodiment 1. Further, the presence of the fifth separated portion 122 can further increase the surface area of the intermediate busbar 110 and further increase the heat dissipation efficiency.

### Embodiment 3

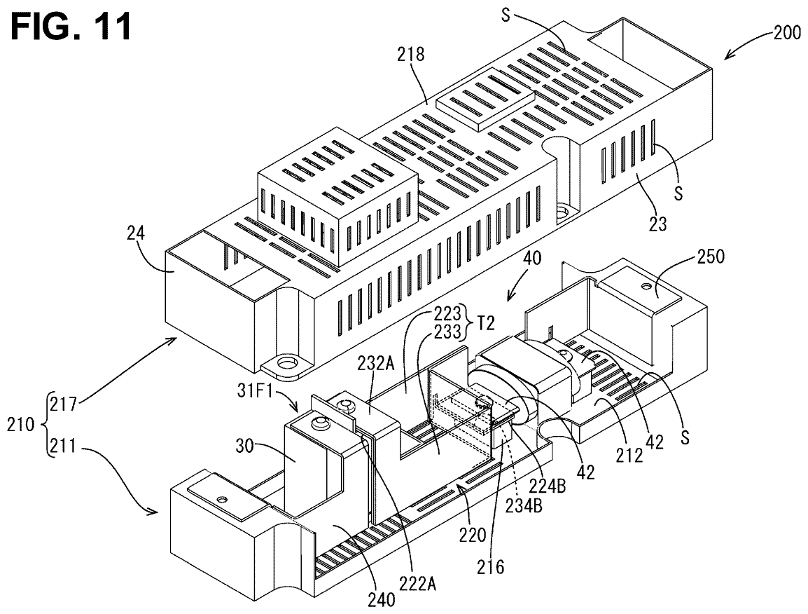

Embodiment 3 will be described with reference to FIGS. 11 to 13. As shown in FIG. 11, an electrical device 200 of Embodiment 3 includes a relay 30, a fuse 40, an intermediate busbar 220 (an example of a busbar), a relay-side busbar 240 (an example of a busbar), a fuse-side busbar 250, and a case 210 that houses these components.

The case 210 is made of synthetic resin and has a base member 211 and a cover 217.

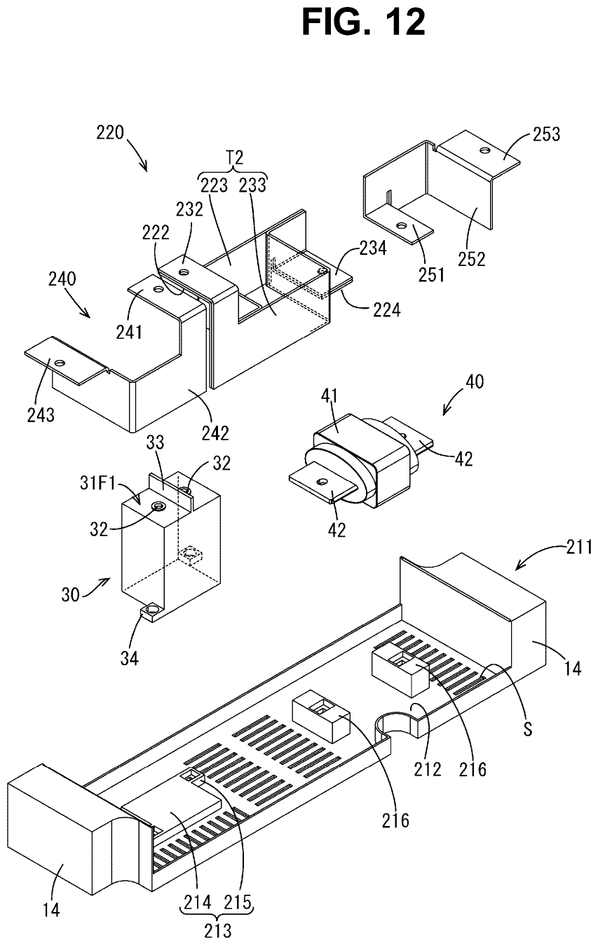

As shown in FIG. 12, the base member 211 includes a base plate 212 (an example of a case wall), two partition walls 13, and two connection stages 14. The base plate 212 has a rectangular plate shape and has a plurality of slits S, as in Embodiment 1. A mount 213 for attaching the relay 30 and two attachment ribs 216 for attaching the fuse 40 are provided in one face of the base plate 212. The mount 213 has a mount body 214 for supporting the relay 30 and two attachment protrusions 215 protruding from the mount body 214. The two attachment ribs 216 each has a rectangular prismatic shape. A nut (not shown) is provided in each of the attachment protrusions 215 and the attachment ribs 216 by means of a known method, such as insert molding or press fitting.

The configuration of the cover 217 is the same as Embodiment 1 except for the detailed shape of the top wall 218, and the same configurations as Embodiment 1 are assigned the same reference signs and description thereof is omitted accordingly.

The relay 30 and the fuse 40 have the same configuration as Embodiment 1, but the directions in which they are attached to the base plate 212 are different. Specifically, the relay 30 is disposed in a direction in which the terminal face 31F1 is parallel with the base plate 212, and the fuse 40 is disposed in a direction in which the fuse terminals 42 are parallel with the base plate 212, as shown in FIG. 11. The shapes of the busbars 220, 240, and 250 are accordingly different from Embodiment 1.

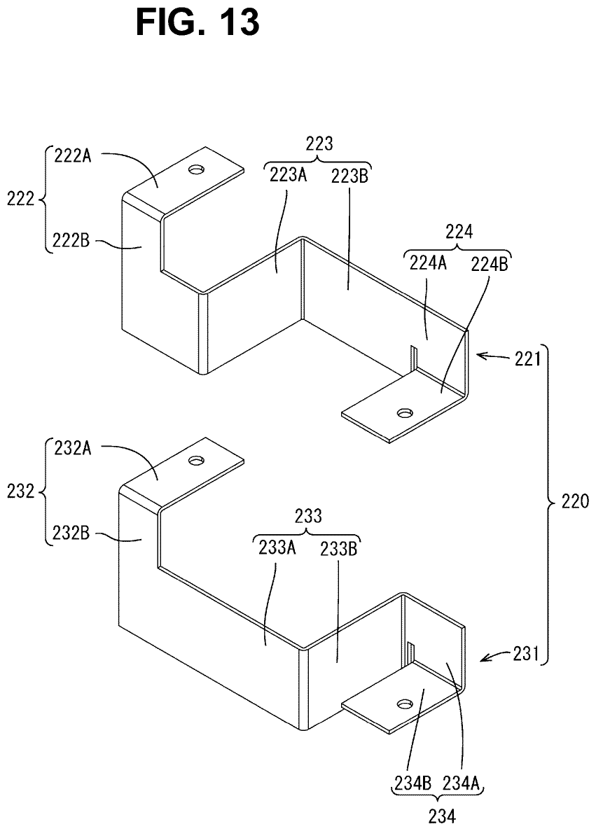

The intermediate busbar 220 includes a seventh busbar strip 221 (an example of one busbar strip) and an eighth busbar strip 231 (an example of another busbar strip), as shown in FIG. 13.

The seventh busbar strip 221 is a member obtained by punching and bending a metal plate material, and has a seventh inner abutting portion 222 (an example of an inner abutting portion and one inner abutting portion), which is connected to one relay terminal 32, a seventh separated portion 223 (an example of one separated portion), which is continuous with the seventh inner abutting portion 222, and a seventh outer abutting portion 224 (an example of an outer abutting portion and one outer abutting portion), which is continuous with the seventh separated portion 223 and connected to one fuse terminal 42. The seventh inner abutting portion 222 has a seventh inner connecting piece 222A having a flat plate shape, and a seventh inner extended portion 222B, which extends perpendicularly from the seventh inner connecting piece 222A. The seventh separated portion 223 has an L-shape, and has a seventh vertical plate portion 223A, which has a flat plate shape and extends perpendicularly from the seventh inner extended portion 222B, and a seventh lateral plate portion 223B, which has a flat plate shape and extends perpendicularly from the seventh vertical plate portion 223A. The seventh outer abutting portion 224 has a seventh outer extended portion 224A, which has a flat plate shape and extends from the seventh lateral plate portion 223B in an opposite direction to the seventh vertical plate portion 223A, and a seventh outer connecting piece 224B, which extends perpendicularly from the seventh outer extended portion 224A.

The eighth busbar strip 231 has an eighth outer abutting portion 232 (an example of an outer abutting portion and another outer abutting portion), which is connected to one relay terminal 32, an eighth separated portion 233 (an example of another separated portion), which is continuous with the eighth outer abutting portion 232, and an eighth inner abutting portion 234 (an example of an inner abutting portion and another inner abutting portion), which is continuous with the eighth separated portion 233 and connected to one fuse terminal 42. The eighth outer abutting portion 232 has an eighth outer connecting piece 232A having a flat plate shape, and an eighth outer extended portion 232B, which extends perpendicularly from the eighth outer connecting piece 232A. The eighth separated portion 233 has an L-shape, and has an eighth lateral plate portion 233A, which has a flat plate shape and extends from the eighth outer extended portion 232B in the same plane, and an eighth vertical plate portion 233B, which has a flat plate shape and extends perpendicularly from the eighth lateral plate portion 233A. The eighth inner abutting portion 234 has an eighth inner extended portion 234A, which has a flat plate shape and extends from the eighth vertical plate portion 233B in an opposite direction to the eighth lateral plate portion 233A, and an eighth inner connecting piece 234B, which extends perpendicularly from the eighth inner extended portion 234A.

As shown in FIG. 12, the seventh inner abutting portion 222 and the eighth outer abutting portion 232 are placed over each other, the seventh outer abutting portion 224 and the eighth inner abutting portion 234 are placed over each other, and the seventh separated portion 223 and the eighth separated portion 233 are separated from each other. The seventh separated portion 223 and the eighth separated portion 233 constitute a ventilation tube portion T2 having a tubular shape.

In a connection region of the intermediate busbar 220 and one relay terminal 32, the seventh inner connecting piece 222A of the seventh inner abutting portion 222 and the eighth outer connecting piece 232A of the eighth outer abutting portion 232 are placed in this order over the relay terminal 32 provided in the terminal face 31F1, as shown in FIG. 11. In a connecting region of the intermediate busbar 220 and one fuse terminal 42, the eighth inner connecting piece 234B of the eighth inner abutting portion 234 and the seventh outer connecting piece 224B of the seventh outer abutting portion 224 are placed in this order over the fuse terminal 42.

The relay-side busbar 240 is a member obtained by punching and bending a metal plate material, and has a relay connecting portion 241, which has a flat plate shape and is connected to one relay terminal 32, a fourth external connection portion 243 for external connection that has a flat plate shape, and a second joint portion 242, which has an L-shape and connects the relay connecting portion 241 to the fourth external connection portion 243, as shown in FIG. 12.

The fuse-side busbar 250 is a member obtained by punching and bending a metal plate material, and has a second fuse connecting portion 251, which has a flat plate shape and is connected to one fuse terminal 42, a fifth external connection portion 253 for external connection that has a flat plate shape, and a third joint portion 252, which has an L-shape and connects the second fuse connecting portion 251 to the fifth external connection portion 253, as shown in FIG. 12.

The present embodiment also achieves the same operation and effect as Embodiment 1.

### Embodiment 4

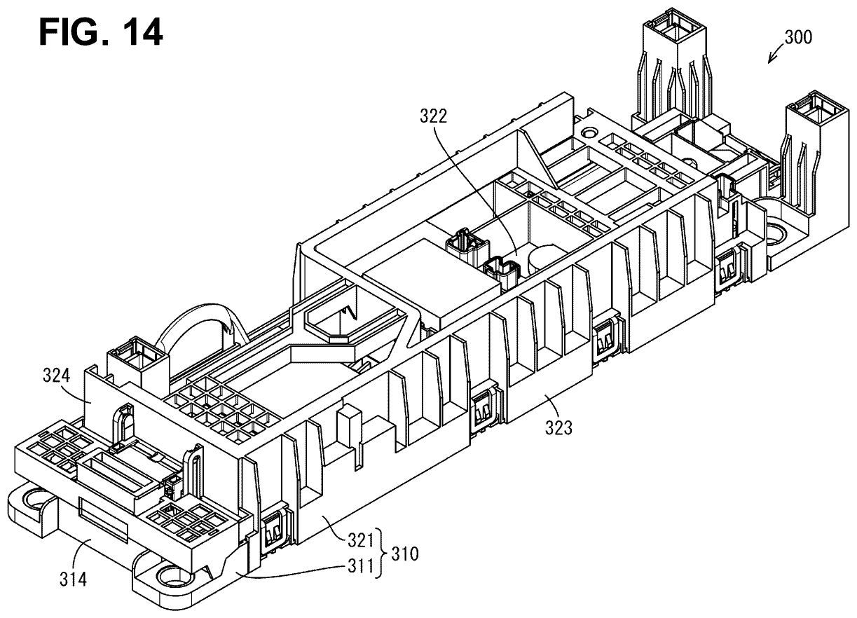

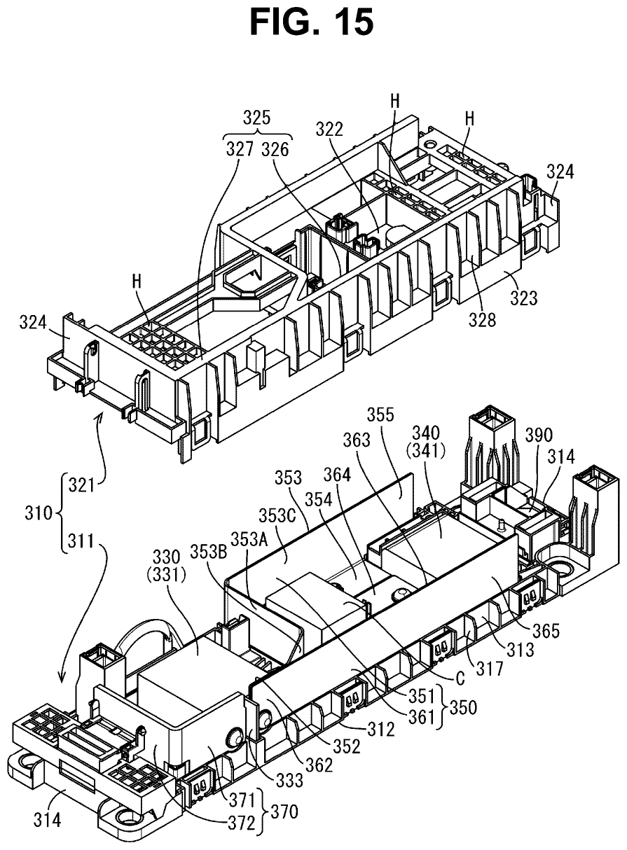

Embodiment 4 will be described with reference to FIGS. 14 to 22. As shown in FIGS. 14 and 15, an electrical device 300 of Embodiment 4 includes a relay 330 (an example of a heat-generating component), a fuse 340 (an example of a heat-generating component), an intermediate busbar 350 (an example of a busbar), a relay-side busbar 370 (an example of a busbar), a fuse-side busbar 390, and a case 310 that houses these components.

### Case 310

The case 310 is made of synthetic resin, and has a base member 311, to which the relay 330 and the fuse 340 are fixed, and a cover 321, which is fitted to the base member 311 and covers the relay 330, the fuse 340, and the busbars 350, 370, and 390, as shown in FIG. 15.

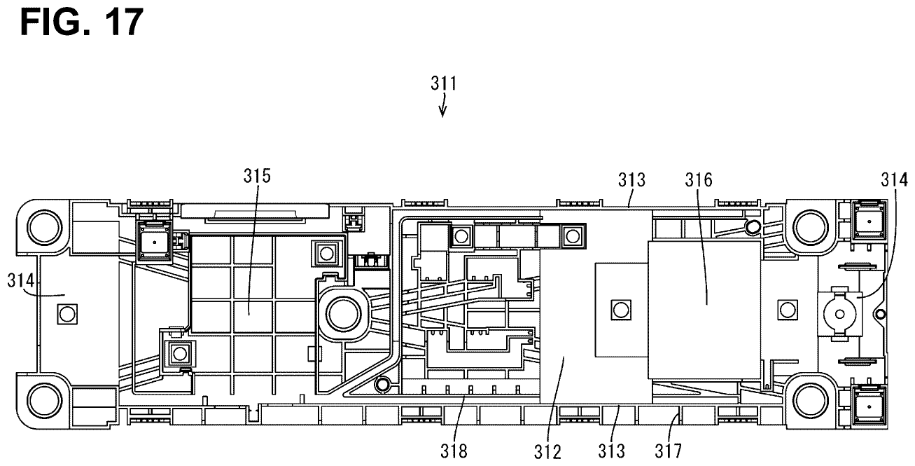

As shown in FIG. 17, the base member 311 has a base plate 312 having a rectangular plate shape, two partition walls 313 rising from two respective long sides of the base plate 312, and two attachment mounts 314 rising from two respective short sides of the base plate 312. A relay attachment portion 315 for attaching the relay 330 and a fuse attachment portion 316 for attaching the fuse 340 are disposed in one face of the base plate 312.

As shown in FIG. 15, the cover 321 has a rectangular plate shape, and has a top wall 322 facing the base plate 312, two first side walls 323 extending from two respective long sides of the top wall 322 along the two respective partition walls 313, two second side walls 324 extending from two respective short sides of the top wall 322, and a busbar housing wall 325 that houses the relay-side busbar 370 and the intermediate busbar 350.

As shown in FIG. 17, a busbar housing wall 318, which is similar to the busbar housing wall 325, is also provided in the base member 311, and the busbar housing wall 325 of the cover 321 is longer in the vertical direction than the busbar housing wall 318 of the base member 311.

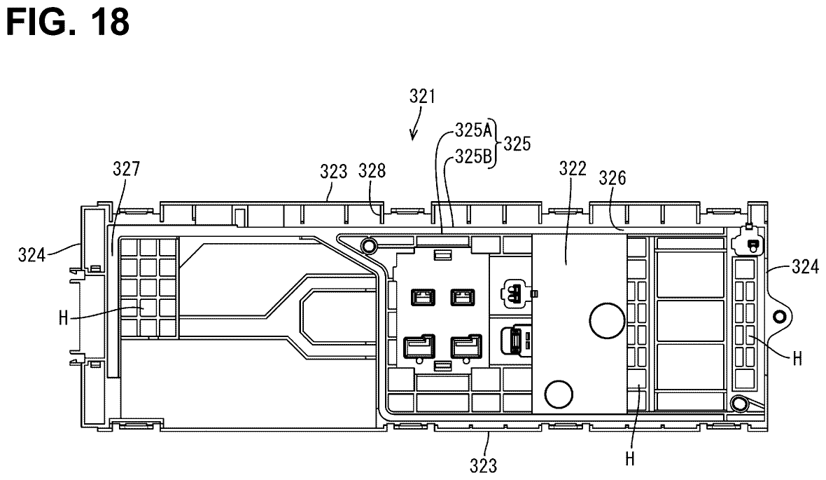

As shown in FIG. 18, a plurality of ventilation holes H for causing the air to flow inside the case 310 are formed in some areas of the top wall 322. It is preferable that each ventilation hole H is as large as possible to the extent that an operator's finger cannot be inserted therein.

### Relay 330 and Fuse 340

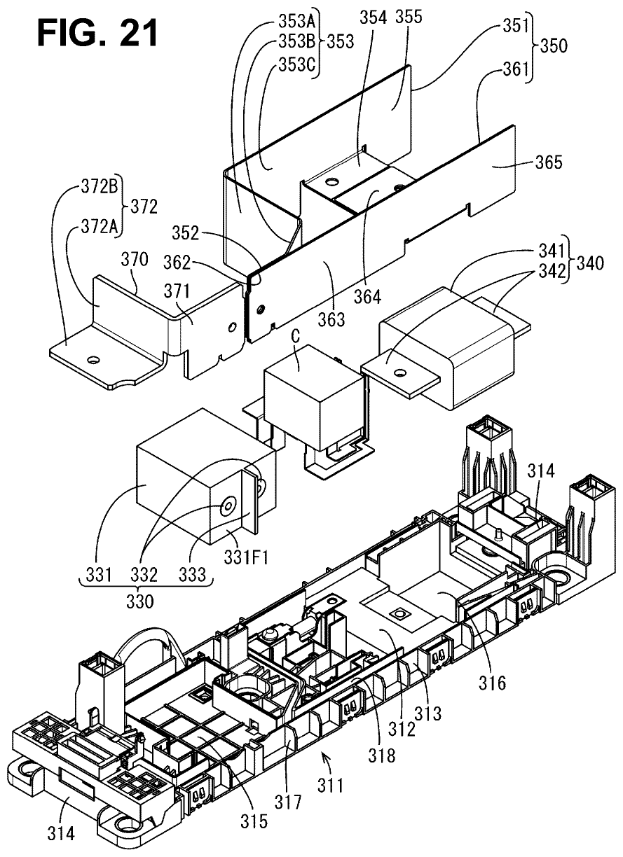

The relay 330 is a mechanical relay through which a relatively large current from the vehicle battery is passed, and has a relay body 331, two relay terminal 332 (each being an example of a terminal), which are disposed in one face (terminal face 331F1) out of a plurality of outer faces of the relay body 331, and a wall 333, as shown in FIG. 21. The two relay terminals 332 are each formed as a nut to which a bolt serving as a fastening member is fastened. The wall 333 is located between the two relay terminals 332 and sets the creepage distance between the two relay terminals 332.

The fuse 340 has a fuse body 341 and two fuse terminals 342 (each being an example of a terminal) protruding from the fuse body 341, as shown in FIG. 21. The fuse terminals 342 are made of metal and has a plate shape.

### Busbars 350, 370, and 390

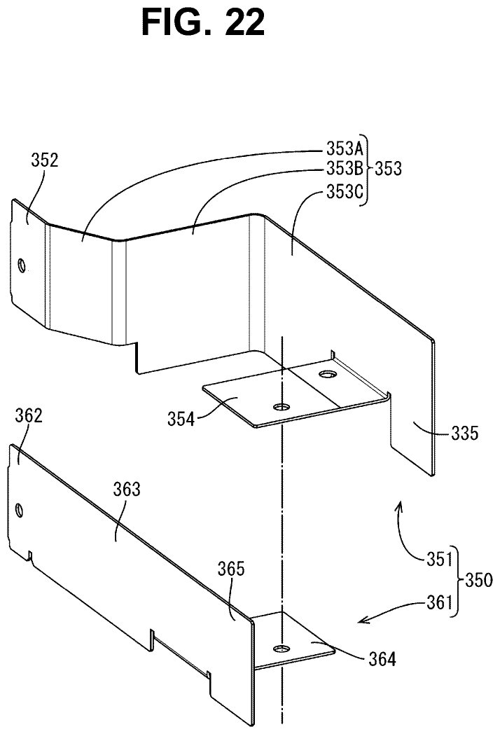

The intermediate busbar 350 is a busbar that connects the relay 330 to the fuse 340, and has a first busbar strip 351 (an example of one busbar strip) and a second busbar strip 361 (an example of another busbar strip), as shown in FIGS. 21 and 22.

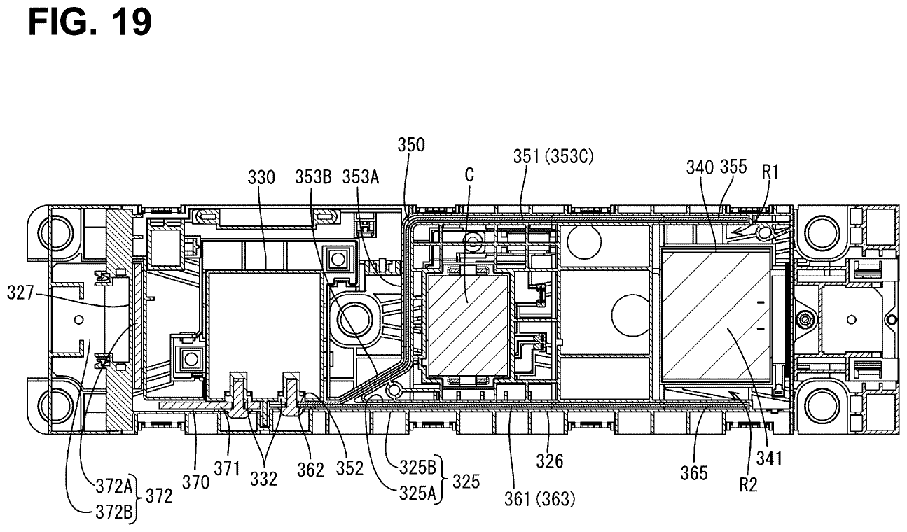

The first busbar strip 351 is a member obtained by punching and bending a metal plate material, and has a first inner abutting portion 352 (an example of an inner abutting portion), which is connected to one relay terminal 332, a first separated portion 353 (an example of one separated portion), which is continuous with the first inner abutting portion 352, a first inner abutting portion 354 (an example of an inner abutting portion), which is continuous with the first separated portion 353 and connected to one fuse terminal 342, and a first extension portion 355 (an example of one extension portion), which is continuous with the first separated portion 353 and extends in a first side region R1 located on a side of the fuse 340, as shown in FIGS. 19 and 22.

The second busbar strip 361 is a member obtained by punching and bending a metal plate material, and has a second outer abutting portion 362 (an example of an outer abutting portion), which is connected to one relay terminal 332, a second separated portion 363 (an example of another separated portion), which is continuous with the second outer abutting portion 362, a second outer abutting portion 364 (an example of an outer abutting portion), which is continuous with the second separated portion 363 and connected to one fuse terminal 342, and a second extension portion 365 (an example of another extension portion), which is continuous with the second separated portion 363 and extends in a second side region R2 located on the opposite side to the first side region R1 relative to the fuse 340. The second separated portion 363 extends linearly from the second outer abutting portion 362.

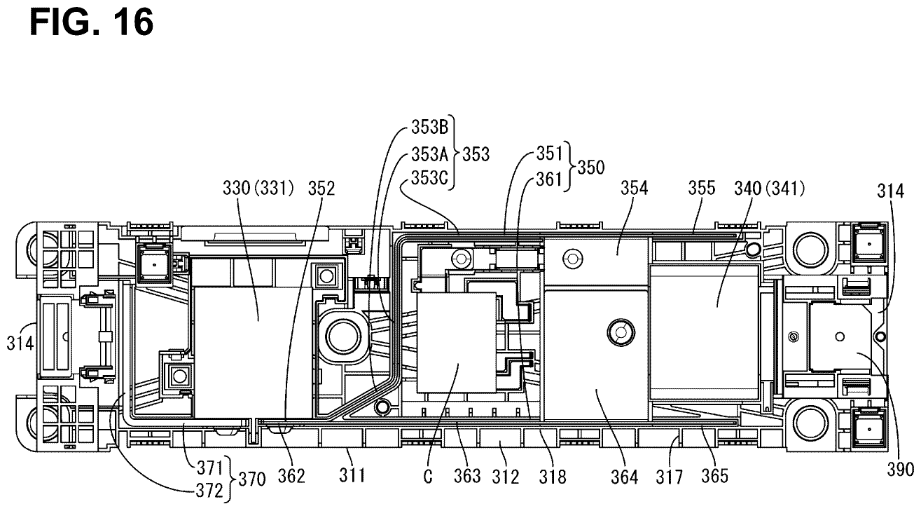

The first inner abutting portion 352 has a flat plate shape. The first separated portion 353 has a first perpendicular portion (an example of one intersecting portion) 353A, which is perpendicular to the second separated portion 363, a first inclined portion 353B, which connects the first inner abutting portion 352 to the first perpendicular portion 353A, and a first parallel portion 353C, which is continuous with the first perpendicular portion 353A and parallel with the second separated portion 363, as shown in FIG. 16. The first inclined portion 353B is inclined so as to extend linearly away from second separated portion 363 while approaching the first perpendicular portion 353A. In the present embodiment, the direction in which the first perpendicular portion 353A extends relative to the second separated portion 363 is an example of a first direction.

The first parallel portion 353C and the first extension portion 355 have a flat plate shape. The first extension portion 355 extends from the first parallel portion 353C in the same plane.

The second outer abutting portion 362, the second separated portion 363, and the second extension portion 365 have a flat plate shape. The second separated portion 363 extends from the second outer abutting portion 362 in the same plane. The second extension portion 365 extends from the second separated portion 363 in the same plane.

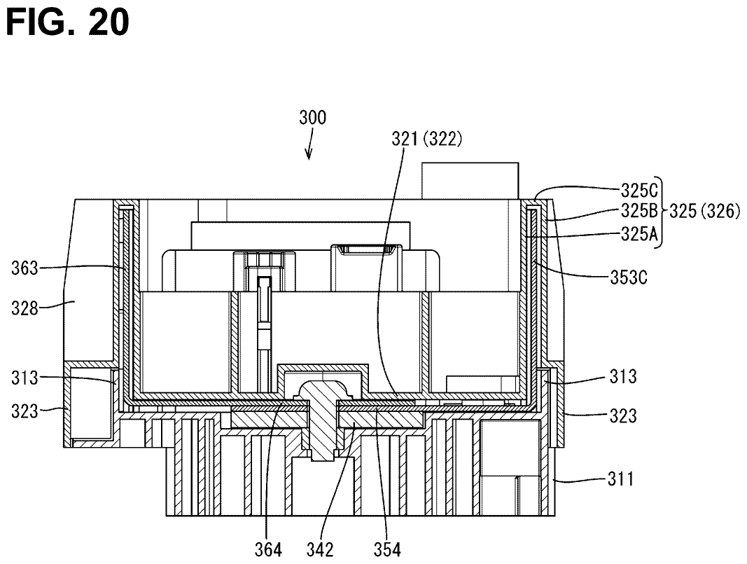

The first inner abutting portion 354 has a flat plate shape. As shown in FIG. 20, the first inner abutting portion 354 extends in a horizontal direction from a lower edge of the first parallel portion 353C toward the second separated portion 363. The second outer abutting portion 364 has a flat plate shape. The second outer abutting portion 364 extends in a horizontal direction from a lower edge of the second separated portion 363 toward the first parallel portion 353C.

The first inner abutting portion 354 abuts one fuse terminal 342 of the fuse 340, and the second outer abutting portion 364 abuts the first inner abutting portion 354. The second outer abutting portion 364, the first inner abutting portion 354, and the fuse terminal 342 are screwed and fixed to each other.

The area of the inner surface, which faces the second separated portion 363, of the first separated portion 353 accounts for 30% or more of the area of the entire inner surface, which faces the second busbar strip 361, of the first busbar strip 351. Similarly, the area of the inner surface, which faces the first separated portion 353, of the second separated portion 363 accounts for 30% or more of the area of the entire inner surface, which faces the first busbar strip 351, of the second busbar strip 361.

As shown in FIG. 21, the relay-side busbar 370 is a busbar for external connection that is connected to the relay 330, and is a member obtained by punching and bending a metal plate material. The relay-side busbar 370 has a relay terminal connecting portion 371, which is connected to one relay terminal 332, and an external connection portion 372 for external connection. The relay terminal connecting portion 371 has a flat plate shape. The external connection portion 372 has a perpendicular portion 372A, which has a flat plate shape and extends in a perpendicular direction from a side edge of the relay terminal connecting portion 371, and a horizontal portion 372B, which has a flat plate shape and extends in a horizontal direction from a lower edge of the perpendicular portion 372A.

The fuse-side busbar 390 is a busbar for external connection that is connected to the fuse 340, as shown in FIG. 16. The fuse-side busbar 390 is a flat plate-shaped member that is obtained by punching and bending a metal plate material, and is connected to one fuse terminal 342.

### Busbar Housing Wall 325

The busbar housing wall 325 includes a first busbar housing wall 326, which houses the intermediate busbar 350, and a second busbar housing wall 327, which houses the relay-side busbar 370, as shown in FIGS. 15 and 18. The first busbar housing wall 326 and the second busbar housing wall 327 have the same configuration, and the first busbar housing wall 326 is described as an example below. Further, the busbar housing wall 318 of the base member 311 is a shorter version, in the vertical direction, of the busbar housing wall 325 of the cover 321, and has the same basic configuration as the busbar housing wall 325. In the following, the busbar housing wall 325 of the cover 321 is described as a representative.

The busbar housing wall 325 (first busbar housing wall 326) has a groove shape formed along the outer shape of the intermediate busbar 350. As shown in FIG. 20, the busbar housing wall 325 has an inner case wall 325A extending along an inner face of the first parallel portion 353C of the first separated portion 353, an outer case wall 325B extending along an outer face of the first parallel portion 353C of the first separated portion 353, and a joint wall 325C extending along an upper end of the first parallel portion 353C of the first separated portion 353.

The joint wall 326C joins an upper end of the inner case wall 326A to an upper end of the outer case wall 326B. The inner case wall 326A and the outer case wall 326B are thus integrated. A lower end of the inner case wall 326A is joined to the top wall 322. A lower end of the outer case wall 326B is joined to an upper end of the first side wall 323.

One partition wall 313 of the base member 311 extends along an outer face of the first parallel portion 353C of the first separated portion 353. The partition wall 313 is housed between the first parallel portion 353C of the first separated portion 353 and the corresponding first side wall 323. The top wall 322 extends along an upper face of the second outer abutting portion 364 of the second separated portion 363.

As shown in FIG. 15, a plurality of cover ribs 328 are formed on an outer face of an outer case wall 325B. A plurality of base ribs 317 are formed on an outer face of each partition wall 313. These ribs 328 and 317 are ribs for reinforcing the busbar housing wall 325 and the partition walls 313, but also function as cooling fins that contribute to improving the heat dissipation efficiency.

As shown in FIG. 20, the first busbar housing wall 326 and the top wall 322 are located close to the intermediate busbar 350, and heat can thus be easily transferred from the intermediate busbar 350 to the first busbar housing wall 326 and the top wall 322. Similarly, the second busbar housing wall 327 is located close to the relay-side busbar 370, and heat can thus be easily transferred from the relay-side busbar 370 to the second busbar housing wall 327. Accordingly, the heat dissipation efficiency can be increased compared to the case of releasing heat into the air from the intermediate busbar 350 and the relay-side busbar 370.

### Assembly Process of Electrical Device 300

One example of an assembly process of the electrical device 300 having the above configuration will be described below.

First, the relay body 331 is placed on the relay attachment portion 315 in a direction in which the terminal face 331F1 is perpendicular to the base plate 312, and then screwed to the base plate 312, thereby fixing the relay 330 to the base member 311.

Next, the first inner abutting portion 352 of the intermediate busbar 350 is disposed so as to be placed over one relay terminal 332 provided in the terminal face 331F1, and the second outer abutting portion 362 is disposed so as to be placed over the first inner abutting portion 352. The first inner abutting portion 352 and the second outer abutting portion 362 are screwed and fixed to the relay terminal 332.

The relay terminal connecting portion 371 of the relay-side busbar 370 is disposed so as to be placed over the other relay terminal 332 provided in the terminal face 331F1, and the relay terminal connecting portion 371 is screwed and fixed to the other relay terminal 332.

When the intermediate busbar 350 has been fixed to the relay 330, the first inner abutting portion 354 of the intermediate busbar 350 has been placed over one fuse terminal 342, and the second outer abutting portion 364 has been placed over the first inner abutting portion 354. In this state, the second outer abutting portion 364, the first inner abutting portion 354, and the fuse terminal 342 are screwed and fixed to each other.

Next, the fuse-side busbar 390 is disposed so as to be placed over the other fuse terminal 342, and the fuse-side busbar 390 is screwed and fixed to the fuse terminal 342. Note that an additional component C, such a relay, may be disposed in the space surrounded by the first perpendicular portion 353A, the first parallel portion 353C, the fuse body 341, and the second separated portion 363.

Fixation of the relay 330, the fuse 340, and the busbars 350, 370, and 390 to the base member 311 is thus completed. Lastly, the cover 321 is fitted to the base member 311, thereby completing assembly of the electrical device 300. When the assembly of the electrical device 300 is complete, the relay 330 has been disposed such that the terminal face 331F1 is perpendicular to the base plate 312, and the fuse 340 has been disposed such that the two fuse terminals 342 are parallel with the base plate 312.

### Passage of Current Through Electrical Device 300

The relay 330 and the fuse 340 generate heat when a current is passed through the electrical device 300 having the above configuration. The heat from the relay 330 and the fuse 340 is dissipated to the busbar housing wall 325 via the busbars 350, 370, and 390, and dissipated into the air from the busbar housing wall 325.

Here, the intermediate busbar 350 includes two busbar strips 351 and 361, and has the first separated portion 353 and the second separated portion 363, as shown in FIG. 16. According to the above configuration, the surface area of the intermediate busbar 350 can be increased to improve the heat dissipation efficiency, while the intermediate busbar 350 can be disposed within a limited space.

Unlike the first vertical plate portion 53A of Embodiment 1, the first perpendicular portion 353A of the first separated portion 353 is short so as to not reach the second separated portion 363. Instead, the first separated portion 353 has the first inclined portion 353B extending diagonally and connecting the first perpendicular portion 353A to the first inner abutting portion 352. With this, the amount of increase in the surface area of the first inclined portion 353B is larger than the amount of decrease in the surface area of the first perpendicular portion 353A, and the surface area of the first separated portion 353 can thus be increased. Moreover, providing the first inclined portion 353B expands the second separated portion 363 and can thus increase the surface area of the second separated portion 363.

### Operation and Effect

The second separated portion 363 extends linearly from the second outer abutting portion 362. The first separated portion 353 has the first perpendicular portion 353A perpendicular to the second separated portion 363, and the first inclined portion 353B connecting the first inner abutting portion 352 to the first perpendicular portion 353A. The first inclined portion 353B is inclined so as to extend away from the second separated portion 363 while approaching the first perpendicular portion 353A.

With this configuration, providing the first inclined portion 353B results in a decrease in the surface area of the first perpendicular portion 353A, but the amount of increase in the surface area of the first inclined portion 353B is larger than the amount of decrease in the surface area of the first perpendicular portion 353A, so that the surface area of the intermediate busbar 350 increases. Further, providing the first inclined portion 353B increases the surface area of the second separated portion 363, thus increasing the surface area of the intermediate busbar 350. Thus, the surface area of the intermediate busbar 350 can be increased in the vicinity of the connecting section to the relay terminal 332 that is likely to generate heat. Particularly, a temperature rise can be prevented during short-term current passage when a large current flows for a short time period.

The case 310 that houses the relay 330, the fuse 340, the intermediate busbar 350, the relay-side busbar 370, and the fuse-side busbar 390 is provided. The case 310 has the inner case wall 325A extending along the inner faces of the busbars (the intermediate busbar 350 and the relay-side busbar 370) and the outer case wall 325B extending along the outer faces of the busbars, and the inner case wall 325A and the outer case wall 325B are integrated. With this configuration, heat is more easily transferred from the inner faces of the busbars to the inner case wall 325A, and from the outer faces of the busbars to the outer case wall 325B, and the heat dissipation efficiency of the busbars can thus be improved compared to the case of dissipating heat into the air.

The electrical device 300 includes a plurality of heat-generating components (the relay 330 and the fuse 340). The relay 330 is located near the first inclined portion 353B and near the first inner abutting portion 352 continuous with the first inclined portion 353B. The first busbar strip 351 also has the first extension portion 355 extending from the first parallel portion 353C in the same plane, for example, toward the first side region R1 located on the side of the fuse 340. The second busbar strip 361 also has the second extension portion 365 extending from the second separated portion 363 in the same plane, for example, toward the second side region R2 located on the opposite side to the first side region R1 relative to the fuse 340. Note that the fuse 340 is dispose at a position farther away from the first inner abutting portion 352 than the relay 330.

With this configuration, the first extension portion 355 and the second extension portion 365 increase the surface area of the intermediate busbar 350, and the heat dissipation efficiency of the intermediate busbar 350 can thus be increased. Further, in general, the temperature is more unlikely to rise in the vicinity of the fuse body 341 than in the vicinity of the fuse terminal 342. The first side region R1 and the second side region R2 of the fuse 340 are regions on the respective sides of the fuse body 341, and are low temperature regions located away from the fuse terminals 342, which are likely to be heat sources. Thus, the heat dissipation efficiency can be improved in the first extension portion 355 and the second extension portion 365.

### Other Embodiments

(1) In Embodiment 1, the rising wall 65 extends from the first outer abutting portion 54, but the rising wall may alternatively extend from the inner abutting portion. Alternatively, rising walls may extend from both the outer abutting portion and the inner abutting portion.

(2) In Embodiments 1 to 3, the base plate 12, the top wall 22, and the two first side walls 23 of the case 10 each have a plurality of slits S. However, the operation and effect are exhibited to a certain degree if the ventilation holes H are provided in at least one area of the case as in Embodiment 4. The case need not necessarily have a ventilation hole.

(3) The relay and the fuse may be attached to the base member in any direction. For example, the relay may be disposed in a direction in which the terminal face is perpendicular to the base member, and the fuse may be disposed in a direction in which the fuse terminals are parallel with the base member. Alternatively, the relay may be disposed in a direction in which the terminal face is parallel with the base member, and the fuse may be disposed in a direction in which the fuse terminals are perpendicular to the base member.

(4) In Embodiments 1 to 3, the ventilation holes are slits. However, each ventilation hole may have any shape, and may have, for example, a circular shape or an elliptic shape, or may be a hole with a polygonal edge.

(5) In the above embodiments, the busbars 50, 70, 90, 110, 220, 240, 250, 350, 370, and 390 are screwed to the relay terminals 32 and 332 and the fuse terminals 42 and 342. However, the busbars may be connected to the terminals of the heat-generating components in any method. For example, the busbars may be connected by means of welding.

(6) In the description of the above embodiments, the mechanical relays 30 and 330 and the fuses 40 and 340 are taken as examples of the heat-generating components. However, the types of heat-generating components are not limited to the embodiments, and may be, for example, a semiconductor switching element, a capacitor, a diode, or the like.

(7) In Embodiment 1, the fourth separated portion 83 extends along the outer face 31F2 of the relay 30. However, both of the two separated portions may extend along the heat-generating component.

(8) In Embodiment 4, the first inclined portion 353B extends linearly, but may alternatively extend in an arc shape.

(9) In Embodiment 4, the base member 311 and the cover 321 have the busbar housing walls 318 and 325, respectively. However, only either the base member 311 or the cover 321 may have the busbar housing wall.

(10) In Embodiment 4, the first extension portion 355 extends toward the first side region R1 of the fuse 340. However, the first extension portion may alternatively extend from the connecting section of the first perpendicular portion 353A and the first parallel portion 353C toward a side region of the relay 330.

(11) In Embodiment 4, the intermediate busbar 350 has both the first extension portion 355 and the second extension portion 365. However, the intermediate busbar may only have the first extension portion 355 or the second extension portion 365.

(12) In the description of Embodiment 4, the extension portions 355 and 365 are disposed in the respective side regions R1 and R2. However, the extension portions need only be disposed in a region near a heat source such as a terminal and where a current does not flow through the busbars. For example, the extension portions may be disposed in a region above or below the fuse body 341. Further, in Embodiment 4, the extension portions 355 and 356 extend from the separated portions 353 and 363 in the same plane, respectively. However, each extension portion need not necessarily extend in the same plane as the corresponding separated portion. Extension portions may alternatively be provided that extend while intersecting the respective separated portions 353 and 363.

(13) In the description of Embodiments 1 to 3, the cases 10 and 210 do not have the busbar housing wall 325 of Embodiment 4. However, Embodiments 1 to 3 may also employ a case having a busbar housing wall.

(14) In the description of Embodiments 1 to 3, the intermediate busbars 50, 110, and 220 do not have the extension portions 355 and 365 of Embodiment 4. However, Embodiments 1 to 3 may also employ an intermediate busbar having an extension portion.

### LIST OF REFERENCE NUMERALS

1 Electrical device
10 Case
11 Base member
12 Base plate (case wall)
13 Partition wall
14 Connection stage
15 Relay mount
16 Mount body
17 Attachment protrusion
18 Attachment pole
21 Cover
22 Top wall (case wall)
23 First side wall (case wall)
24 Second side wall
30 Relay (heat-generating component)
31 Relay body
31F1 Terminal face
31F2 Outer face
32 Relay terminal (terminal)
33 Wall
34 Attachment piece
40 Fuse (heat-generating component)
41 Fuse body
42 Fuse terminal (terminal)
50 Intermediate busbar (busbar)
51 First busbar strip (one busbar strip)
52 First inner abutting portion (inner abutting portion, one inner abutting portion)
53 First separated portion (one separated portion)
53A First vertical plate portion
53B First lateral plate portion
54 First outer abutting portion (inner abutting portion, one outer abutting portion)
61 Second busbar strip (another busbar strip)
62 Second outer abutting portion (outer abutting portion, another outer abutting portion)
63 Second separated portion (another separated portion)
63A Second lateral plate portion
63B Second vertical plate portion
64 Second inner abutting portion (inner abutting portion, another inner abutting portion)
65 Rising wall
70 Relay-side busbar (busbar)
71 Third busbar strip (one busbar strip)
72 Third inner abutting portion (inner abutting portion)
73 Third separated portion (one separated portion)
74 First external connection portion
81 Fourth busbar strip (another busbar strip)
82 Fourth outer abutting portion (outer abutting portion)
83 Fourth separated portion (another separated portion)
84 Second external connection portion
90 Fuse-side busbar
91 First fuse connecting portion
92 First joint portion
93 Third external connecting portion
100 Electrical device
110 Intermediate busbar (busbar)
111 Fifth busbar strip (another busbar strip)
121 Sixth busbar strip (another busbar strip)
122 Fifth separated portion (another separated portion)
123, 124 Intermediate abutting portion (outer abutting portion)
200 Electrical device
210 Case
211 Base member
212 Base plate
213 Mount
214 Mount body
215 Attachment protrusion
216 Attachment rib
217 Cover
218 Top wall
220 Intermediate busbar (busbar)
221 Seventh busbar strip (first busbar strip)
222 Seventh inner abutting portion (inner abutting portion, one inner abutting portion)
222A Seventh inner connecting piece
222B Seventh inner extended portion
223 Seventh separated portion (one separated portion)
223A Seventh vertical plate portion
223B Seventh lateral plate portion
224 Seventh outer abutting portion (outer abutting portion, one outer abutting portion)
224A Seventh outer extended portion
224B Seventh outer connecting piece
231 Eighth busbar strip (another busbar strip)
232 Eighth outer abutting portion (outer abutting portion, another outer abutting portion)
232A Eighth outer connecting piece
232B Eighth inner extended portion
233 Eighth separated portion (another separated portion)
233A Eighth lateral plate portion
233B Eighth vertical plate portion
234 Eighth inner abutting portion (inner abutting portion, another inner abutting portion)
234A Eighth inner extended portion
234B Eighth inner connecting piece
240 Relay-side busbar
241 Relay connecting portion
242 Second joint portion
243 Fourth external connecting portion
250 Fuse-side busbar
251 Second fuse connecting portion
252 Third joint portion
253 Fifth external connection portion
300 Electrical device
310 Case
311 Base member
312 Base plate
313 Partition wall
314 Attachment table
315 Relay attachment portion
316 Fuse attachment portion
317 Base-side rib
318 Busbar housing wall
321 Cover
322 Top wall
323 First side wall
324 Second side wall
325 Busbar housing wall
325A Inner case wall
325B Outer case wall
325C Joint wall
326 First busbar housing wall
327 Second busbar housing wall
328 Cover rib
330 Relay
331 Relay body
331F1 Terminal face
332 Relay terminal
333 Wall
340 Fuse
341 Fuse body
342 Fuse terminal
350 Intermediate busbar
351 First busbar strip
352 First inner abutting portion (inner abutting portion)
353 First separated portion
353A First perpendicular portion (one intersecting portion)
353B First inclined portion
353C First parallel portion
354 First inner abutting portion (inner abutting portion)
355 First extension portion (one extension portion)
361 Second busbar strip
362 Second outer abutting portion (outer abutting portion)
363 Second separated portion
364 Second outer abutting portion (outer abutting portion)
365 Second extension portion (another extension portion)
370 Relay-side busbar
371 Relay terminal connecting portion
372 External connection portion
372A Perpendicular portion
372B Parallel portion
390 Fuse-side busbar
C Additional component
H Ventilation hole
R1 First side region
R2 Second side region
S Slit (ventilation hole)
T1, T2 Ventilation tube portion

The invention claimed is:

1. An electrical device comprising:
a heat-generating component that has a terminal and generates heat in response to passage of a current; and
a busbar connected to the terminal,
wherein the busbar includes:
one busbar strip having: an inner abutting portion connected to the terminal; and
one separated portion continuous with the inner abutting portion; and
another busbar strip having: an outer abutting portion abutting the inner abutting portion; and another separated portion continuous with the outer abutting portion and separated from the one separated portion.

2. The electrical device according to claim 1,
wherein an area of an inner surface, which faces the other separated portion, of the one separated portion accounts for 30% or more of an area of an entire inner surface, which faces the other busbar strip, of the one busbar strip.

3. The electrical device according to claim 1,
wherein the one separated portion and the other separated portion are disposed in a space adjacent to the heat-generating component.

4. The electrical device according to claim 1,
wherein the busbar has a rising wall rising from the outer abutting portion or the inner abutting portion.

5. The electrical device according to claim 1,
wherein the electrical device comprises a plurality of the heat-generating components,
the one busbar strip has one inner abutting portion serving as the inner abutting portion and one outer abutting portion serving as the outer abutting portion that are continuous with the one separated portion, and the other busbar strip has another inner abutting portion serving as the inner abutting portion and another outer abutting portion serving as the outer abutting portion that are continuous with the other separated portion, and
the one inner abutting portion and the other outer abutting portion are placed in this order over the terminal of one heat-generating component of the plurality of heat-generating components, and the other inner abutting portion and the one outer abutting portion are placed in this order over the terminal of another heat-generating component of the plurality of heat-generating components.

6. The electrical device according to claim 1,
wherein the busbar has a ventilation tube portion having a tubular shape and constituted by the one separated portion and the other separated portion.

7. The electrical device according to claim 1,
wherein the one separated portion and the other separated portion are perpendicular to each other.

8. The electrical device according to claim 7,
wherein at least either the one separated portion or the other separated portion extends along an outer face of the heat-generating component.

9. The electrical device according to claim 1, further comprising
a case housing the heat-generating component and the busbar,
wherein the case includes a case wall having a ventilation hole.

10. The electrical device according to claim 9,
wherein the case includes the case wall extending along the one separated portion or the other separated portion.

11. The electrical device according to claim 6, further comprising
a case housing the heat-generating component and the busbar,
wherein the case includes a case wall that has a ventilation hole and is perpendicular to the ventilation tube portion.

12. The electrical device according to claim 1,
wherein the other separated portion extends linearly from the outer abutting portion,
the one separated portion has: one intersecting portion extending in a first direction intersecting the other separated portion; and one inclined portion connecting the inner abutting portion to the one intersecting portion, and
the one inclined portion inclines so as to extend away from the other separated portion while approaching the one intersecting portion.

13. The electrical device according to claim 1, further comprising
a case housing the heat-generating component and the busbar,
wherein the case includes: an inner case wall extending along an inner face of the busbar; and an outer case wall extending along an outer face of the busbar, the inner case wall and the outer case wall being integrated.

14. The electrical device according to claim 1,
wherein the busbar further has at least either:
one extension portion extending from the one separated portion toward a first side region located on a side of the heat-generating component, or
another extension portion extending from the other separated portion toward a second side region located on an opposite side to the first side region relative to the heat-generating component.
